(19) United States
(12) Patent Application Publication
(10) Pub. No.: US 2007/0080381 A1
(43) Pub. Date: Apr. 12, 2007

(54) Robust protective layer for MTJ devices

(75) Inventors: Chen-Jung Chien, Sunnyvale, CA (US); Yu-Hsia Chen, Mountain View, CA (US); Chyu-Jiuh Torng, Pleasanton, CA (US); Cherng-Chyi Han, San Jose, CA (US)

Correspondence Address: STEPHEN B. ACKERMAN, 28 DAVIS AVENUE, POUGHKEEPSIE, NY, 12603, US

(73) Assignee: MagIC Technologies, Inc.

(21) Appl. No.: 11/248,965

(22) Filed: Oct. 12, 2005

(51) Int. Cl. H01L 29/94

(52) U.S. Cl. 257/295

(57) ABSTRACT

MTJ devices commonly degrade when subjected to the heat treatments required by subsequent further processing. This problem has been overcome by protecting the MTJ's sidewalls with a two layer laminate. The first layer is laid down under oxygen-free conditions, no attempt being made to replace any oxygen that is lost during the deposition. This is followed immediately by the deposition of the second layer (usually, but not mandatorily, of the same material as the first layer) in the presence of some oxygen.

### FIELD OF THE INVENTION

The invention relates to the general field of magnetic disk storage with particular reference to the ability of the tunnel junction to withstand significant heat treatment.

### BACKGROUND OF THE INVENTION

Magnetic tunnel junctions (MTJs) are commonly used for both magnetic read heads and for MRAM (magnetic random access memory) storage elements. An example of the former is illustrated in FIG. 1. Using a lower magnetic shield (not shown) as a substrate, the layers making up the device include seed layer 11, antiferromagnetic layer 12, pinned layer 13, insulating tunneling layer 14, free layer 15, and capping layer 16. Ion beam milling has been used to form sloping sidewalls on three sides, the fourth side (which lies in the plane of the figure) being planar and comprising the air bearing surface.

Since the edges of the tunneling barrier layer are exposed after the milling processes, a thin insulating layer (17 in FIG. 1) is necessary to encapsulate the MTJ so as to prevent shorting of the tunneling barrier layer by hard bias layers 18 or by the top conducting lead (not shown) that will be added later. The quality of this encapsulation film can affect both the MTJ resistance and its stability. In particular, the resistance of a MTJ device may increase when it is subjected to the heat treatments that are associated with the subsequent formation of the write head.

An MTJ of the prior art suitable for use as a MRAM storage element is shown in FIG. 2. It is similar to the stricture of FIG. 1 except that the sloping side walls are present on all four sides (so the cross-section seen in FIG. 2 could have been taken at any of the sides) and there are no longitudinal stabilization (hard bias) layers. As in FIG. 1, protection of the exposed portions of tunneling layer 14 has been accomplished by means of a single encapsulation layer 17. In this device the substrate on which the MTJ stack is grown is a lower conducting lead (not shown) while layer 28 represents the device's top conducting lead.

Control of the resistance of a MTJ is thus a key issue for making a successful magnetic recording head due to the latter's high sensitivity to both the tunneling barrier quality and to the insulation process selected to isolate the MTJ from surrounding conductive material. A common process for forming a MTJ for magnetic recording head applications is to first ion mill the magnetic tunneling film under a photo mask to define the magnetic track width, followed by the deposition of a hard bias layer to stabilize the junction domain. A similar second ion milling process perpendicular to the first is then used to define the magnetic stripe height. Finally, a top conducting lead is deposited on the MTJ device.

In MRAM applications, the MTJ is formed by ion milling or reactive ion etching (RIE) the magnetic tunneling film under the defined photo mask or hard mask. In a photoresist liftoff process, one deposits the encapsulation layer onto the MTJ immediately after the device has been formed, following which the resist is chemically lifted off together with any material sticking to it.

A top conducting lead is directly deposited on the MTJ device. In another approach by chemical mechanical polishing (CMP), the photoresist is lifted away before a thicker encapsulation layer is deposited on to the MTJ device. Then a CMP process is applied to flatten and expose the junction surface to the conducting lead. The large MTJ resistance due to the tunneling barrier can vary significantly depending on the quality of this encapsulating layer.

A routine search of the prior art was performed with the following references of interest being found:

In U.S. Pat. Nos. 6,884,630 (Gupta et al) and 6,784,091 (Nuetzal et al), conventional encapsulating layers are described. U.S. Pat. No. 6,518,588 (Parkin et al) discloses a Ta/TaN encapsulation layer deposited in two steps.

Slaughter et al. (U.S. Pat. No. 6,544,801) teach depositing an oxygen deficient layer, for example, Al, which is oxidized fully in subsequent heating steps. U.S. Pat. No. 6,764,960 (Hibino) teaches sputtering alumina without O₂, then adding O₂ to the sputtering chamber to oxidize the Al and form a tunneling barrier film.

### SUMMARY OF THE INVENTION

It has been an object of at least one embodiment of the present invention to provide an MTJ stack that may be subjected to heat treatment without an increase in its tunneling resistance or a decrease in its tunneling breakdown voltage.

Another object of at least one embodiment of the present invention has been to provide a process for manufacturing said improved MTJ stack.

Still another object of at least one embodiment of the present invention has been that said process not require significant modifications to existing processes for manufacturing MTJ stacks.

A further object of at least one embodiment of the present invention has been that said improved MTJ stack perform as least as well as MTJ stacks of the prior art in areas not affected by the invention.

These objects have been achieved by protecting the MTJ stack's sidewalls with a two layer laminate. The first layer is laid down under oxygen-free conditions, no attempt being made to replace any oxygen that is lost during the deposition. This is followed immediately by the deposition of the second layer (usually, but not mandatorily, of the same material as the first layer) in the presence of some oxygen. It has been found that two layer laminates of this type enable the protected device to be subsequently heat treatment without an increase in the tunneling resistance or a decrease in the breakdown voltage.

### BRIEF DESCRIPTION OF THE DRAWINGS

FIG. 1 shows a magnetic read head of the prior art that includes a single insulating layer on its sidewalls.

FIG. 2 shows a magnetic memory element of the prior art that includes a single insulating layer on its sidewalls.

FIG. 3 shows the structure seen in FIG. 2, modified according to the teachings of the present invention.

FIG. 4 shows the structure seen in FIG. 1, modified according to the teachings of the present invention.

### DESCRIPTION OF THE PREFERRED EMBODIMENTS

To resolve the problem of tunnel junction instability we have used a lamination process for the encapsulation layer deposition. The first portion of the laminated film is deposited on to the MTJ by sputtering (or other suitable deposition process) any dielectric material target such as Al₂O₃, SiO₂, AlNx, SiNx, etc in an oxygen-free environment. The second portion of the film is immediately deposited but in the presence of a partial oxygen pressure of between about 0.5 and 5 mtorr. As a result, the first layer contains no additional embedded oxygen atoms and acts as an oxygen stopper to the second layer with oxygen which helps enhance the breakdown voltage of the entire film.

The final deposited encapsulation film maintains a good breakdown voltage as can be seen in TABLE I and, additionally, it is stable with respect to resistance increases associataed with any subsequent heat treatment (of up to about 250° C. for up to about 300 minutes).

This is shown in Table II

TABLE I
Breakdown voltages (Mv/cm)

| | Single encapsulating | Dual laminated |
|---|---|---|
| Sample | layer | encapsulation |
| 1 | 6.55 | 7.04 |
| 2 | 5.42 | 7.28 |
| 3 | 6.20 | 7.19 |
| 4 | 5.56 | 7.37 |
| 5 | 6.42 | 7.65 |

TABLE II
Resistance increase after heating at 250° C. for 300 minutes

| | | % resistance |
|---|---|---|
| Sample | Encapsulation | increase |
| 3GJN | Dual laminate | 0 |
| 3H3N | Dual laminate | 0 |
| 3C8N | Single layer | 66 |
| 3CFN | Single layer | 70 |

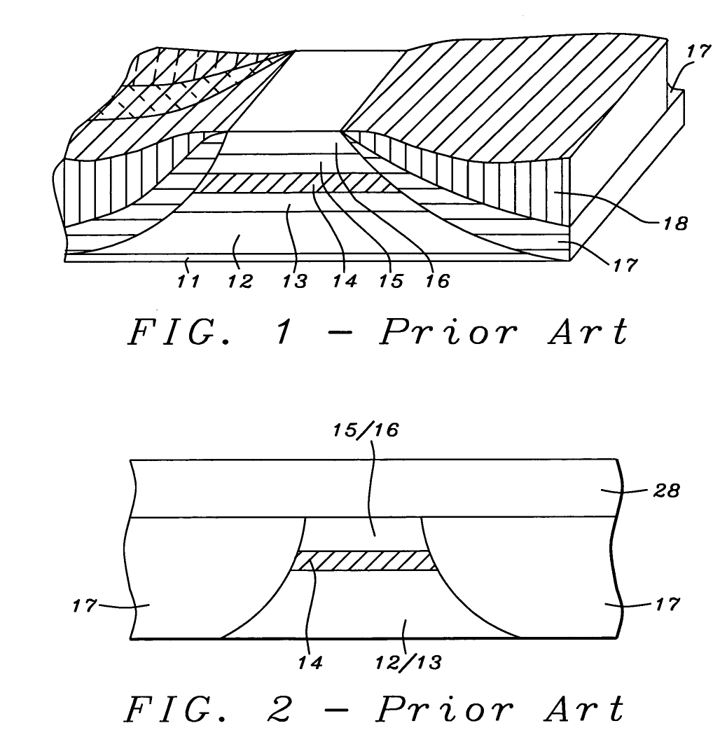

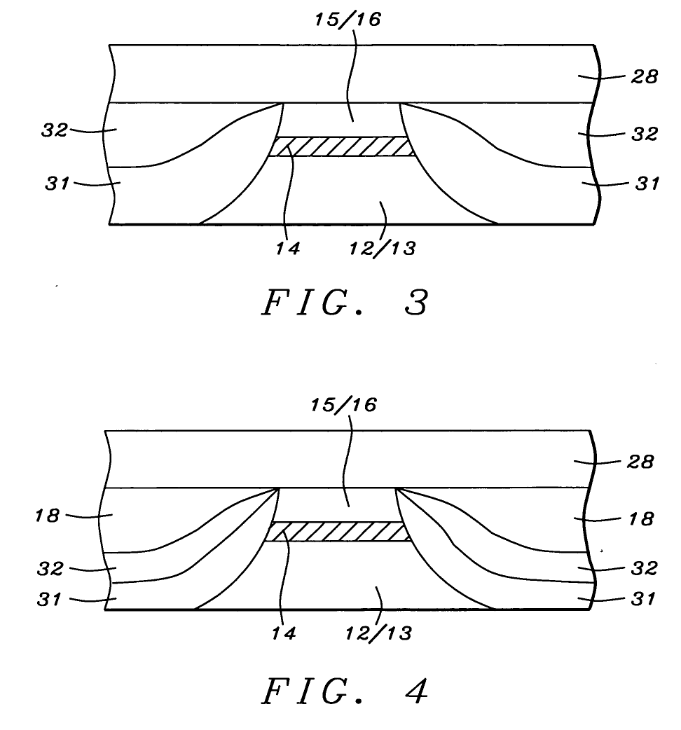

Referring now to FIG. 3, we illustrate the process of the invention by describing formation of an MRAM storage element. The process begins with the provision of a lower magnetic shield layer (not shown) as the substrate. Then (as referenced in FIG. 1) seed layer 11 is deposited. This is followed by the successive depositions of antiferromagnetic layer 12, pinned layer 13, insulating tunneling layer 14, free layer 15, and capping layer 16. As discussed earlier the MTJ stack is then provided with sidewalls by means of ion milling down as far as the substrate.

Now follows a key novel feature of the invention, namely the deposition of the first of two encapsulation layers (layer 31) using a suitable deposition method such as sputtering. The deposition of layer 31 must take place in an oxygen-free atmosphere. Any oxygen that gets lost due to dissociation of the deposited material is not replaced during this step.

Then, in a second key step, a second encapsulation layer (layer 32) is deposited on first encapsulating layer 31, this time under a partial oxygen pressure of at least 0.1 mtorr. Typically, first encapsulating layer 31 is between about 50 and 400 Angstroms thick while second encapsulating layer 32 is also between about 50 and 400 Angstroms thick. While both encapsulating layers will generally be deposited from the same material the process does not require this to be the case. Typical materials for the encapsulating layers include (but are not limited to) Al₂O₃, SiO₂, AlNₓ, and SiNₓ.

The process just described immediately above can be applied with equal facility to the formation of a magnetic read element, the main difference being that sloping sidewalls are formed on only three sides and, as illustrated in FIG. 4, hard bias layer 18 is formed on the two layer encapsulating laminate.

For both these device types, the resulting two layer laminate described above has been found to provide excellent protection for the tunneling layer from oxidation during subsequent heat treatments. Data confirming this is presented in TABLES I and II below:

What is claimed is:

1. A method to encapsulate a magnetic tunnel junction, comprising:
providing an MTJ stack having sidewalls and including an insulating tunneling layer lying between a pinned and a free layer;
in an oxygen-free atmosphere, depositing a first encapsulating layer on said sidewalls; and
then, under a partial oxygen pressure of at least 0.1 mtorr, depositing a second encapsulating layer on said first encapsulating layer.

2. The method of claim 1 wherein said first encapsulating layer is between about 50 and 400 Angstroms thick.

3. The method of claim 1 wherein said second encapsulating layer is between about 50 and 400 Angstroms thick.

4. The method of claim 1 wherein the same material is deposited to form said second encapsulating layer as was used to deposit said first encapsulating layer.

5. The method of claim 4 wherein said first encapsulating layer is selected from the group consisting of Al₂O₃, SiO₂, AlNₓ, and SiNₓ.

6. A process to form a magnetic device, comprising:
on a substrate, depositing a seed layer;
depositing an antiferromagnetic layer on said seed layer;
depositing a pinned layer on said antiferromagnetic layer;
depositing an insulating tunneling layer on said pinned layer;
depositing a free layer on said insulating tunneling layer;
depositing a capping layer on said free layer;
by means of ion milling down as far as said substrate, forming an MTJ stack, having sidewalls;
in an oxygen-free atmosphere, depositing a first encapsulating layer on said sidewalls; and
then, under a partial oxygen pressure of at least 0.1 mtorr, depositing a second encapsulating layer on said first encapsulating layer, thereby protecting said tunneling layer from oxidation during possible subsequent heat treatments.

7. The process recited in claim 6 wherein said first encapsulating layer is between about 50 and 400 Angstroms thick.

8. The process recited in claim 6 wherein said second encapsulating layer is between about 50 and 400 Angstroms thick.

9. The process recited in claim 6 wherein the same material is deposited to form said second encapsulating layer as was used to deposit said first encapsulating layer.

10. The process recited in claim 9 wherein said first encapsulating layer is selected from the group consisting of Al₂O₃, SiO₂, AlNₓ, and SiNₓ.

11. The process recited in claim 6 wherein said MTJ stack is a read head having three sloping sidewalls and a planar air bearing surface,

12. The process recited in claim 6 wherein said MTJ stack is a MRAM storage element.

13. The process recited in claim 6 wherein said tunneling layer has a thickness of about 8 Angstroms and a breakdown voltage of 2 volts or less.

14. The process recited in claim 6 wherein said tunneling layer has a resistance increase of no more than about 1% after being heated at a temperature of up to about 250° C. for up to about 300 minutes.

15. A protected MTJ structure comprising:
a vertical stack, having sidewalls, said stack further comprising:
a seed layer on a substrate;
an antiferromagnetic layer on said seed layer;
a pinned layer on said antiferromagnetic layer;
an insulating tunneling layer on said pinned layer;
a free layer on said insulating tunneling layer, and
a capping layer on said free layer;
on said sidewalls, a first encapsulating layer of a material capable of capturing oxygen atoms; and
on said first encapsulating layer, a second encapsulating layer that includes some oxygen, whereby said tunneling layer is protecting from oxidation during possible subsequent heat treatments.

16. The MTJ structure described in claim 15 wherein said MTJ stack is a read head having three sloping sidewalls and a planar air bearing surface,

17. The MTJ structure described in claim 15 wherein said MTJ stack is a MRAM storage element.

18. The MTJ structure described in claim 15 wherein said first encapsulating layer is between about 50 and 400 Angstroms thick.

19. The MTJ structure described in claim 15 wherein said second encapsulating layer is between about 50 and 400 Angstroms thick.

20. The MTJ structure described in claim 15 wherein said encapsulating layers are selected from the group consisting of Al₂O₃, SiO₂, AlNₓ, and SiNₓ.

21. The MTJ structure described in claim 15 wherein said tunneling layer has a thickness of about 5 Angstroms and a breakdown voltage of 2 volts or less.

22. The MTJ structure described in claim 15 wherein said tunneling layer has a resistance increase of no more than about 1% after being heated at a temperature of up to about 250° C. for up to about 300 minutes.
